(19) United States
(12) Patent Application Publication
(10) Pub. No.: US 2014/0127901 A1
(43) Pub. Date: May 8, 2014

(54) LOW-K DAMAGE FREE INTEGRATION SCHEME FOR COPPER INTERCONNECTS

(71) Applicant: TAIWAN SEMICONDUCTOR MANUFACTURING COMPANY, L, Hsin-Chu (TW)

(72) Inventors: Chih Wei Lu, Hsin-Chu City (TW); Chung-Ju Lee, Hsin-Chu (TW); Tien-I Bao, Dayuan Township (TW)

(73) Assignee: Taiwan Semiconductor Manufacturing Company, Ltd., Hsin-Chu (TW)

(21) Appl. No.: 13/672,358

(22) Filed: Nov. 8, 2012

(51) Int. Cl. H01L 21/768

(52) U.S. Cl. 438/653; 257/E21.584

(57) ABSTRACT

A method includes forming a sacrificial layer on a substrate. A hard mask layer is formed on the sacrificial layer. The hard mask layer and the sacrificial layer are etched to form a first plurality of openings in the hard mask layer and the sacrificial layer. A low-k dielectric layer is deposited in the first plurality of openings. The hard mask layer and the sacrificial layer are thereafter removed leaving behind a plurality of low-k dielectric pillar structures having second plurality of openings therebetween. The second plurality of openings are then filled with a copper-containing layer.

### BACKGROUND

An important objective in the advancement of integrated circuit (IC) technology is the reduction of IC dimensions. Such reduction of IC dimensions reduces area capacitance and is critical to increasing the performance of integrated circuits. Moreover, reducing the area of an IC die leads to higher yield in IC fabrication. Such advantages are among the driving forces to constantly scale down IC dimensions.

As the density of semiconductor devices increases, however, the resistance capacitance (RC) delay time increasingly dominates the circuit performance. To reduce the RC delay, there is a desire to switch from conventional dielectrics to low-k dielectrics, which have a dielectric constant less than SiO₂, or about 4. Low-k dielectrics may also include a class of low-k dielectrics frequently called extreme low-k (ELK) dielectrics, which have a dielectric constant less than about 2.5. Low-k materials are particularly useful as intermetal dielectrics (IMDs) and as interlayer dielectrics (ILDs). Despite their advantages, low-k materials raise many problems relating to their integration into conventional processing methods.

One process integration issue of particular concern is in the formation of conductive interconnect structures, such as in the damascene process. The damascene process typically includes etching with a high-energy plasma. The low-k materials are susceptible to damage from a plasma etch because they are softer, less chemically stable, more porous, or any combination of these factors. The plasma damage manifests itself in higher leakage currents, lower breakdown voltages, and changes in the dielectric constant associated with the low-k dielectric material. Some damaged low-k dielectrics are easily deformed during exposure to wet chemical cleanups, which results in the loss of critical dimension (CD) structures.

In view of these and other process integration problems facing low-k dielectrics, there is a need for new semiconductor methods and structures.

### BRIEF DESCRIPTION OF DRAWINGS

Embodiments of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart of a method of fabricating a copper interconnect structure according to various embodiments of the present disclosure.

FIGS. 2-9 are cross-sectional views of a portion of a copper interconnect structure at various stages of fabrication in accordance with various embodiments of the present disclosure.

### DETAILED DESCRIPTION

In the following description, specific details are set forth to provide a thorough understanding of embodiments of the present disclosure. However, one having an ordinary skill in the art will recognize that embodiments of the disclosure can be practiced without these specific details. In some instances, well-known structures and processes are not described in detail to avoid unnecessarily obscuring embodiments of the present disclosure.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

The present disclosure relates generally to semiconductor device fabrication and more specifically to low-k and/or extreme low-k (ELK) dielectric formation. The present disclosure will now be described with respect to exemplary embodiments in a specific context, namely the creation of an ELK dielectric and copper conductive lines in a damascene process. It is believed that embodiments of this invention are particularly advantageous in the damascene interconnect process. A significant advantage of embodiments is the ease at which they are integrated into back end of line (BEOL) processing applications. It is further believed that embodiments described herein will benefit other integrated circuit applications wherein dielectric processing damage, dielectric formation, and metal line buckling are a concern. Therefore, the specific embodiments discussed are merely illustrative of specific ways to make and use the invention, and do not limit the scope of the invention.

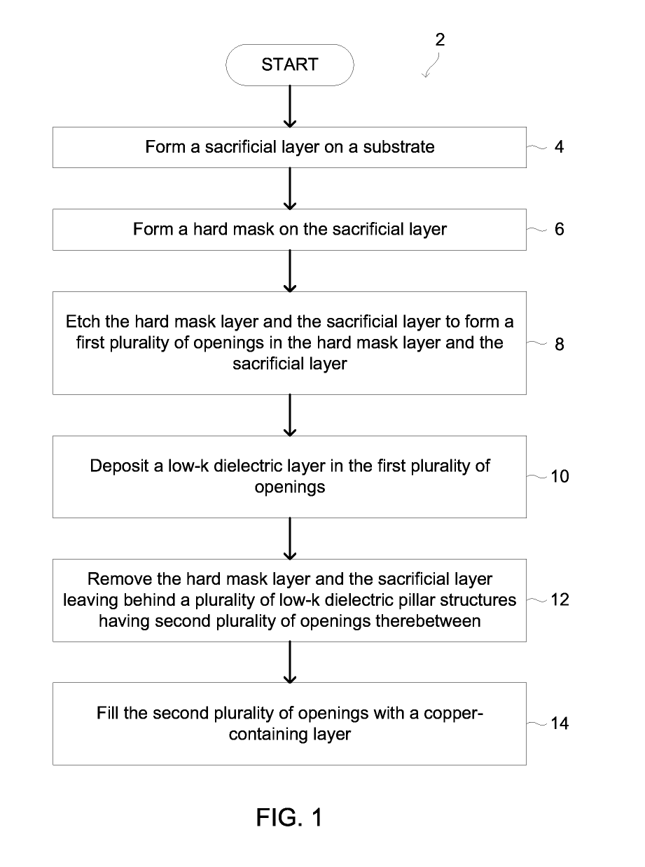

FIG. 1 is a flowchart of a method 2 for fabricating a copper interconnect structure according to various aspects of the present disclosure. Referring to FIG. 1, the method includes block 4, in which a sacrificial layer is formed on a substrate. The method 2 includes block 6, in which a hard mask layer is formed on the sacrificial layer. The method 2 includes block 8, in which the hard mask layer and the sacrificial layer are etched to form a first plurality of openings in the hard mask layer and the sacrificial layer. The method 2 includes block 10, in which a low-k dielectric layer is deposited in the first plurality of openings. The method 2 includes block 12, in which the hard mask layer and the sacrificial layer are removed leaving behind a plurality of low-k dielectric pillar structures having a second plurality of openings therebetween. The method 2 includes block 14, in which the second plurality of openings is filled with a copper-containing layer.

It is understood that additional processes may be performed before, during, or after the blocks 4-14 shown in FIG. 1 to complete the fabrication of the copper interconnect structure, but these additional processes are not discussed herein in detail for the sake of simplicity.

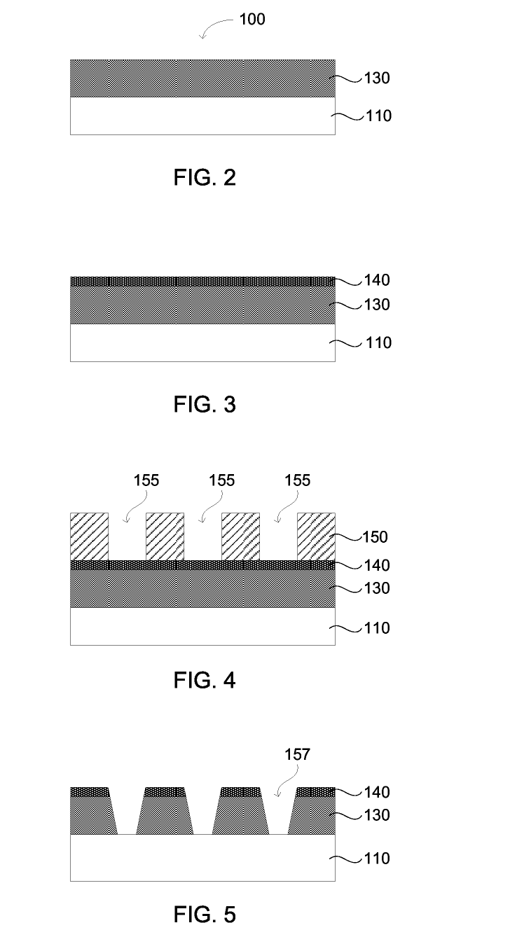

FIGS. 2-8 are cross-sectional views of a portion of a copper interconnect structure at various stages of fabrication according to embodiments of the method 2 of FIG. 1. It is understood that FIGS. 2-8 have been simplified for a better understanding of the inventive concepts of the present disclosure. It should be appreciated that the materials, geometries, dimensions, structures, and process parameters described herein are exemplary only, and are not intended to be, and should not be construed to be, limiting to the invention claimed herein. Many alternatives and modifications will be apparent to those skilled in the art, once informed by the present disclosure.

Referring now to FIG. 2, there is shown a cross section of a device 100 at an intermediate semiconductor fabrication stage. Included in device 100 is a substrate 110, which may comprise silicon, silicon on insulator (SOI), Ge, SiC, GaAs, GaAlAs, InP, GaN, or SiGe. The substrate 110 may further comprise a conductive feature such as functional and logic devices, a FET (or a component thereof such as a source, a drain region, or an electrode gate), conductors, levels of wiring, other interconnected layers, active or passive devices, or combinations thereof.

FIG. 2 also illustrates a sacrificial layer 130 formed on the substrate 110. In one embodiment, the sacrificial layer 130 is formed of a non-organic material selected from un-doped silicate glass (USG), silicon nitride, silicon oxynitride, silicon oxide, and combinations thereof. In another embodiment, the sacrificial layer 130 is formed of a polymer layer, such as an epoxy, polyimide, benzocyclobutene (BCB), polybenzoxazole (PBO), and the like, although other relatively soft, often organic, dielectric materials can also be used. In one embodiment, the sacrificial layer 130 is a polyimide layer. Sacrificial layer 130 may be formed on substrate 110 by spin coating or other commonly used methods. The thickness of sacrificial layer 130 is between about 10 nm to about 500 nm It is understood that the dimensions recited are merely examples, and will change with the down scaling of integrated circuits.

Turning now to FIG. 3, a hard mask layer 140 is deposited on the sacrificial layer 130. The hard mask layer 140 may be a single or multiple layers. Suitable hard mask materials include nitrides, such as tungsten nitride, silicon nitride, and tantalum nitride; oxides such as silicon oxide; silicides such as tungsten silicide; and mixtures of these substances such as silicon oxynitride. The hard mask layer 140 may be deposited on the sacrificial layer 130 using standard deposition techniques, including physical vapor deposition (PVD) and chemical vapor deposition (CVD). In one embodiment, the hard mask layer 140 is deposited to a thickness of between about 1 nm to about 100 nm As discussed above, it is understood that the dimensions recited are merely examples, and will change with the down scaling of integrated circuits.

Referring now to FIG. 4, using conventional photolithographic processes a photoresist layer is applied on hard mask layer 140, exposed, patterned, and then etched to form a patterned photoresist layer 150 having openings 155. The patterned photoresist layer 150 is used as an etching mask on the surface of the hard mask layer 140 overlying the sacrificial layer 130, for etching trench openings through the sacrificial layer 130. With the patterned photoresist layer 150 stripped away by plasma ash, for example, the trench openings are subsequently filled with a low-k dielectric layer, as will be described below.

With reference to FIG. 5, openings 155 are etched sequentially through the hard mask layer 140 and the sacrificial layer 130 to form trenches 157 and, in one embodiment the trenches 157 stopping on the substrate 110. Reactant gas mixtures and etching parameters are adjusted for each layer to achieve a high etch rate for each layer as it is reached. An endpoint sensor, such as an optical emission spectrometer, provides continuous monitoring of the etching process and indicates when etchant gases are to be changed to accommodate either a nitride layer or a polymer layer, for example. In an exemplary embodiment, the nitride layers are etched with a gas mixture containing a fluorocarbon such as CF₄ , CHF₃ , CH₂F₂ , or C₄F₈ while the polymer layers are etched without flurocarbons, for example N₂, N₂/H₂, or NH₃. In an exemplary embodiment, the hard mask layer 140 and the sacrificial layer 130 are etched using an O₂ free plasma or gas. In some embodiments, the hard mask layer 140 and the sacrificial layer 130 are etched using an O₂ plasma. Etchant gas mixtures and plasma parameters for etching the various layers are well known to those skilled in the art and may be experimentally optimized for each application. FIG. 5 shows the interconnect structure following the step of etching the hard mask layer 140 and the sacrificial layer 130.

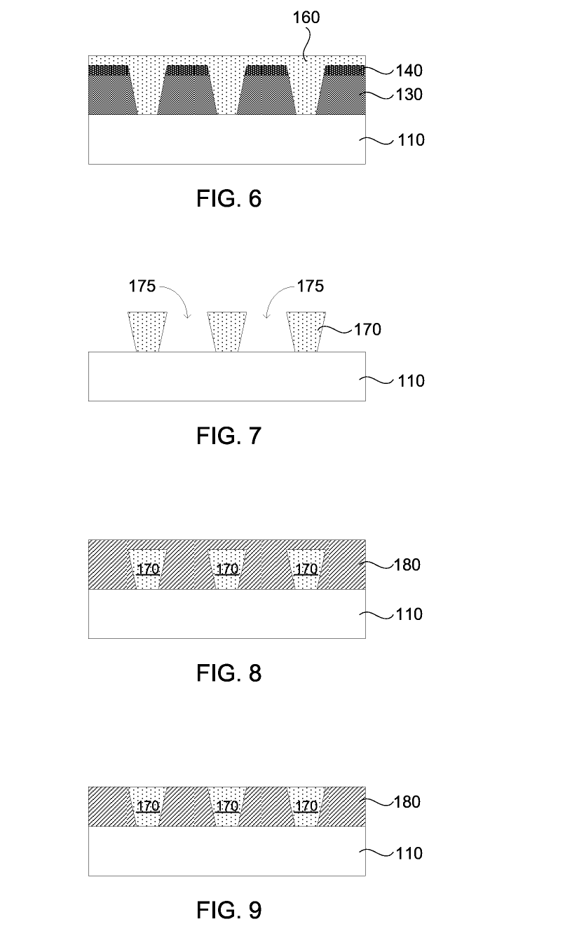

In FIG. 6, a low-k dielectric layer 160 is next formed over the substrate 110 and deposited in the trenches 157. The low-k dielectric layer 160 may comprise a low-dielectric constant material such as methyl silsesquioxane (MSQ), a MSQ derivative, hydridosilsesquioxane (HSQ), a HSQ derivative, an oxide and MSQ hybrid, a porogen/MSQ hybrid, an oxide and HSQ hybrid, a porogen/HSQ hybrid, or combinations thereof, as examples. Alternatively, the low-k dielectric layer 160 may comprise a porous dielectric. In other embodiments, the low-k dielectric layer 160 comprises other low-dielectric constant materials, such as nanoporous silica, xerogel, polytetrafluoroethylene (PTFE), or low-dielectric constant (low-k) materials such as SiLK available from Dow Chemicals of Midland, Mich., Flare, available from Allied Signal of Morristown, N.J., and Black Diamond, available from Applied Materials of Santa Clara, Calif., as examples, although other low-k materials may also be used. The low-k dielectric layer 160 is in one embodiment deposited using a chemical vapor deposition (CVD) or a spin-on coating technique, although other deposition techniques may alternatively be used. The low-k dielectric layer 160 is deposited to a thickness of about 10 nm to about 500 nm, for example, although is may comprise other thicknesses. One skilled in the art will recognize that the thickness range will be a matter of design choice and will likely decrease as device critical dimensions shrink and processing controls improve over time.

Following deposition, the low-k dielectric layer 160 may be cured to harden the dielectric layer. The curing may be performed in a Rapid Thermal Processing (RTP) equipment with a radiation source. In one embodiment, the curing process lasts between approximately one to ten minutes and occurs at a temperature of approximately 250 degrees Celsius to around 450 degrees Celsius. Alternatively, the curing may be done by e-beam or UV curing.

Following the curing step, the low-k dielectric layer 160 and the hard mask layer 140 are then be planarized by conventional techniques such as chemical mechanical planarization (CMP) so that a top surface of the low-k dielectric layer 160 is substantially co-planar with a top surface of the sacrificial layer 130. The planarization step prepares the device 100 for the next step in the fabrication process where the sacrificial layer is removed.

In FIG. 7, the sacrificial layer 130 is removed. According to an exemplary embodiment, the sacrificial layer 130 is removed by an etch process having an O₂ free plasma or gas, such as N₂, N₂/H₂, NH₃, or CO, for example leaving a plurality of low-k pillars 170 standing and openings 175 in-between the pillars 170. According to another embodiment, the sacrificial layer 130 is removed by heating the substrate 110 to a temperature above 200 Celsius for about 1 second to about 600 minutes. According to yet another embodiment, the sacrificial layer 130 is removed by UV radiation. According to yet another embodiment, the sacrificial layer 130 is removed by a wet strip process known to those skilled in the art.

Continuing with FIG. 8, a copper-containing layer 180 is deposited to fill the opening 175. Deposition of the copper-containing layer 180 may be by physical vapor deposition (PVD) methods such as sputtering or vacuum evaporation, or by CVD (chemical vapor deposition), electroless plating, or by electro-chemical plating (ECP). In ECP, a copper layer forms on the low-k pillars 170 and fills the openings 175. The copper layer could include substantially pure elemental copper, copper containing unavoidable impurities, and copper alloys containing minor amounts of elements such as tantalum, indium, tin, zinc, manganese, chromium, titanium, germanium, strontium, platinum, magnesium, niobium, aluminum or zirconium.

In alternative embodiments, the deposition may be by ECD (electrochemical deposition). The ECD method involves placing the wafer into an electrolyte bath and electroplating a metal layer onto the wafer surface by applying an electric field between the wafer and the electrolyte. The ECD method is desirable for the deposition of copper because of its superior gap-filling and step coverage. Following ECD deposition (or other deposition technique) the copper-containing layer 180 is planarized by chemical mechanical planarization (CMP) to expose the low-k pillars 170 underneath completing the formation of the damascene metallization and forming the structure of FIG. 9. Thereafter, conventional processing methods may complete the device fabrication.

In some embodiments, prior to depositing the copper-containing layer 180 over the substrate 110 to fill the openings 175, a barrier seed layer (not shown) may be blanket formed on the low-k pillars 170 to line the sidewalls and top of the low-k pillars 170 by chemical vapor deposition (CVD), plasma vapor deposition (PVD), or atomic vapor deposition (ALD). The materials of the seed layer include copper or copper alloys, and metals such as silver, gold, aluminum, and combinations thereof may also be included. The seed layer may also include aluminum or aluminum alloys. In an exemplary embodiment, the barrier seed layer is formed by an anneal process in which heat is applied to the substrate 110 to a temperature greater than about 200 Celsius such that the barrier seed layer is self-forming In one embodiment, the self-formed barrier layer has a thickness from about 1 Angstrom to about 300 Angstroms. In another embodiment, the seed layer is formed by sputtering. In other embodiments, other commonly used methods such as physical vapor deposition or electroless plating may be used.

Embodiments of the invention provide many advantages in the fabrication of devices having low-k and/or ELK dielectrics. For example, in some embodiments there is no etch/ash/wet strip damage to a porous ELK at a trench sidewall; therefore, a lower k value results. In some embodiments, O₂ free plasma etching is used to avoid damage to the low-k dielectric material. In some embodiments, there is no Cu diffusion into porous ELK dielectrics caused by harsh barrier/seed deposition. In some embodiments, there is no or reduced line buckling caused by a low modulus of the low-k dielectric material. Also, in some embodiments, there is no additional tooling as embodiments are easily integrated into existing CVD and CMP processes, and the etching processes used are easy to control. Also included in the list of advantages of some embodiments are reduced RC delay and reduced parasitic capacitance.

The present disclosure has described various exemplary embodiments. According to one embodiment, a method includes forming a sacrificial layer on a substrate. A hard mask layer is formed on the sacrificial layer. The hard mask layer and the sacrificial layer are etched to form a first plurality of openings in the hard mask layer and the sacrificial layer. A low-k dielectric layer is deposited in the first plurality of openings. The hard mask layer and the sacrificial layer are thereafter removed leaving behind a plurality of low-k dielectric pillar structures having second plurality of openings therebetween. The second plurality of openings are then filled with a copper-containing layer.

According to another embodiment, a method for fabricating a semiconductor device having a low-k dielectric layer includes forming a passivation layer on a substrate. A sacrificial layer is formed on the passivation layer. A hard mask layer is formed on the sacrificial layer. A photoresist layer is formed on the hard mask layer, the photoresist layer having a first pattern of openings. The first pattern of openings is etched into the hard mask layer and the sacrificial layer to expose portions of the passivation layer, the etching using an O₂ free plasma etching. A low-k dielectric layer is deposited in the first pattern of openings. The low-k dielectric layer is then cured. The hard mask layer and the sacrificial layer are then removed leaving behind a plurality of low-k dielectric pillar structures having second pattern of openings therebetween. A copper-containing layer is deposited in the second pattern of openings.

According to yet another embodiment, a method for fabricating a semiconductor device having a low-k dielectric layer, includes depositing a polymer-containing layer on a first low-k dielectric layer of a substrate. A hard mask layer is deposited on the sacrificial layer. A patterned photoresist layer is deposited on the hard mask layer, the photoresist layer having a first pattern of openings. The first pattern of openings are etched into the hard mask layer and the sacrificial layer to expose a portion of the first low-k dielectric layer, the etching using an O₂ free plasma etching. A low-k dielectric layer is deposited in the first pattern of openings. The second low-k dielectric layer is thereafter cured. The second low-k dielectric layer is planarized so that a top surface of the second low-k dielectric layer is substantially co-planar with a top surface of the polymer-containing layer. The polymer-containing layer is removed leaving behind a plurality of low-k dielectric pillar structures having second pattern of openings therebetween. A barrier seed layer is deposited along sidewalls of the second pattern of openings and a copper-containing layer is deposited on the barrier seed layer.

In the preceding detailed description, specific exemplary embodiments have been described. It will, however, be apparent to a person of ordinary skill in the art that various modifications, structures, processes, and changes may be made thereto without departing from the broader spirit and scope of the present disclosure. The specification and drawings are, accordingly, to be regarded as illustrative and not restrictive. It is understood that embodiments of the present disclosure are capable of using various other combinations and environments and are capable of changes or modifications within the scope of the claims.

1. A method comprising:
forming a sacrificial layer on a substrate;
forming a hard mask layer on the sacrificial layer;
etching the hard mask layer and the sacrificial layer to form a first plurality of openings in the hard mask layer and the sacrificial layer;
depositing a low-k dielectric layer in the first plurality of openings;
removing the hard mask layer and the sacrificial layer leaving behind a plurality of low-k dielectric pillar structures having [a] second plurality of openings therebetween; and
filling the second plurality of openings with a copper-containing layer.

2. The method of claim 1, wherein the sacrificial layer is a polymer, epoxy, polyimide, benzocyclobutene (BCB), polybenzoxazole (PBO), or neopentyl methacrylate-co-ethylene glycol dimethacrylate.

3. The method of claim 1, wherein the etching the hard mask layer and the sacrificial layer comprises etching using an O₂ free plasma.

4. The method of claim 1, wherein the low-k dielectric layer has a thickness from about 10 nm to about 500 nm.

5. The method of claim 1, wherein the low-k dielectric layer is a porous dielectric layer.

6. The method of claim 1, further comprising:
curing the low-k dielectric layer.

7. The method of claim 1, further comprising:
planarizing the low-k dielectric layer so that a top surface of the low-k dielectric layer is substantially co-planar with a top surface of the sacrificial layer.

8. The method of claim 1, wherein the removing the sacrificial layer comprises etching using an O₂ free plasma.

9. The method of claim 1, further comprising:
prior to filling the second plurality of openings with a copper-containing layer, depositing a barrier seed layer in the second plurality of openings.

10. The method of claim 1, further comprising:
annealing the substrate to form a self-formed barrier layer on the top and sidewalls of each of the plurality of low-k dielectric pillar structures.

11. The method of claim 9, further comprising:
planarizing the copper-containing layer so that a top surface of the copper-containing layer is substantially co-planar with a top surface of the low-k dielectric layer.

12. A method for fabricating a semiconductor device having a low-k dielectric layer, the method comprising:
forming a passivation layer on a substrate;
forming a sacrificial layer on the passivation layer;
forming a hard mask layer on the sacrificial layer;
forming a photoresist layer on the hard mask layer, the photoresist layer having a first pattern of openings;
etching the first pattern of openings into the hard mask layer and the sacrificial layer to expose portions of the passivation layer;
depositing a low-k dielectric layer in the first pattern of openings;
curing the low-k dielectric layer;
removing the hard mask layer and the sacrificial layer leaving behind a plurality of low-k dielectric pillar structures having a second pattern of openings therebetween; and
depositing a copper-containing layer in the second pattern of openings.

13. The method of claim 12, further comprising:
developing the photoresist layer; and
removing the photoresist layer.

14. The method of claim 12, wherein the sacrificial layer is a material comprising epoxy, polyimide, benzocyclobutene (BCB), polybenzoxazole (PBO), or neopentyl methacrylate-co-ethylene glycol dimethacrylate.

15. The method of claim 12, wherein the etching the hard mask layer and the sacrificial layer comprises etching using an O₂ free plasma.

16. The method of claim 12, further comprising:
prior to depositing a copper-containing layer in the second pattern of openings, depositing a barrier seed layer in the second pattern of openings.

17. The method of claim 12, further comprising:
annealing the substrate to form a self-formed barrier layer on the top and sidewalls of each of the plurality of low-k dielectric pillar structures.

18. The method of claim 16, further comprising:
planarizing the copper-containing layer so that a top surface of the copper-containing layer is substantially co-planar with a top surface of the low-k dielectric layer.

19. A method for fabricating a semiconductor device having a low-k dielectric layer, the method comprising:
depositing a polymer-containing layer on a first low-k dielectric layer of a substrate;
depositing a hard mask layer on the polymer-containing layer;
depositing a patterned photoresist layer on the hard mask layer, the photoresist layer having a first pattern of openings;
etching the first pattern of openings into the hard mask layer and the polymer-containing layer to expose a portion of the first low-k dielectric layer;
depositing a second low-k dielectric layer in the first pattern of openings;
curing the second low-k dielectric layer;
planarizing the second low-k dielectric layer so that a top surface of the second low-k dielectric layer is substantially co-planar with a top surface of the polymer-containing layer;
removing the polymer-containing layer leaving behind a plurality of low-k dielectric pillar structures having a second pattern of openings therebetween;
depositing a barrier seed layer along sidewalls of the second pattern of openings; and
depositing a copper-containing layer on the barrier seed layer.

20. The method of claim 19, wherein the polymer-containing layer has a thickness range from about 10 nm to about 500 nm and is a material comprising epoxy, polyimide, benzocyclobutene (BCB), polybenzoxazole (PBO), or neopentyl methacrylate-co-ethylene glycol dimethacrylate.
